(19) United States
(12) Patent Application Publication
(10) Pub. No.: US 2025/0311479 A1
(43) Pub. Date: Oct. 2, 2025

(54) Device for Converting Electromagnetic Radiation into Electricity, and Related Systems and Methods

(71) Applicants: Thomas J Nugent, Jr., Kent, WA (US); LaserMotive, Inc., Kent, WA (US)

(72) Inventors: Thomas J. NUGENT, JR., Bellevue, WA (US); Thomas W. BASHFORD, Renton, WA (US); David BASHFORD, Kent, WA (US); Jordin T. KARE, San Jose, CA (US)

(73) Assignee: LaserMotive, Inc., Kent, WA (US)

(21) Appl. No.: 19/206,973

(22) Filed: May 13, 2025

Related U.S. Application Data
(63) Continuation-in-part of application No. 18/509,200, filed on Nov. 14, 2023, now Pat. No. 12,300,755.
Application No. 18/509,200 is a continuation of application No. 17/080,542, filed on Oct. 26, 2020, now abandoned.
Application No. 17/080,542 is a division of application No. 14/263,858, filed on Apr. 28, 2014, now Pat. No. 10,825,944.
(60) Provisional application No. 61/816,784, filed on Apr. 28, 2013.

(51) Int. Cl. H10F 77/42; F21S 11/00; G01S 3/78; G01S 3/786; G02B 3/08; G02B 5/00; G02B 17/08; G02B 19/00; G02B 21/04; G02B 27/09; H02S 20/00; H02S 20/32; H10F 19/00; H10F 77/40; H10F 77/63

(52) U.S. Cl. CPC H10F 77/488; F21S 11/00; G01S 3/78; G01S 3/7861; G02B 3/08; G02B 5/001; G02B 17/084; G02B 17/086; G02B 19/0023; G02B 19/0028; G02B 19/0033; G02B 19/0038; G02B 19/009; G02B 21/04; G02B 27/0911; G02B 27/0983; H02S 20/00; H02S 20/32; H10F 19/00; H10F 77/40; H10F 77/484; H10F 77/68; Y02E 10/52

(57) ABSTRACT

A device for converting electromagnetic radiation (e.g., nonuniform laser light) into electricity comprises an expander that includes a conical shape having an axis and a curved surface that is configured to reflect electromagnetic radiation away from the axis to expand a beam of the electromagnetic radiation; and one or more energy conversion components configured to receive a beam of electromagnetic radiation expanded by the expander, and to generate electricity from the expanded beam of electromagnetic radiation. With the expander's curved surface, a beam of electromagnetic radiation that is highly concentrated—has a large radiation flux—may be converted into a beam that has a larger cross-sectional area. Moreover, one can configure, if desired, the curved surface to provide a substantially uniform distribution of radiation across the expanded cross-sectional area. With such an expanded beam the one or more energy conversion components can efficiently convert the electromagnetic radiation into electricity.

### CROSS-REFERENCE TO RELATED APPLICATIONS AND PRIORITY CLAIMS

This application claims priority under 35 U.S.C. § 121 as a continuation-in part of commonly owned U.S. patent application Ser. No. 18/509,200, filed Nov. 14, 2023, issued May 13, 2025 as U.S. Pat. No. 12,300,755, which is a continuation of commonly owned U.S. patent application Ser. No. 17/080,542, filed Oct. 26, 2020, which is a divisional of commonly owned U.S. patent application Ser. No. 14/263,858, filed Apr. 28, 2014, issued Nov. 3, 2020, as U.S. Pat. No. 10,825,944, which claimed priority under 35 U.S.C. § 119(e) to commonly owned U.S. Provisional Patent Application No. 61/816,784, filed Apr. 28, 2013. Each of these previous patent applications is incorporated by reference herein.

### BACKGROUND

Laser light or other monochromatic light sources can be converted into electricity using photovoltaic converters comprising an array of photovoltaic cells. Multiple cells or groups of cells may be connected in series, to raise the output voltage of the array compared to the output voltage of one cell.

When laser power is transmitted through free space, photovoltaic receivers may be physically configured similarly to solar photovoltaic arrays, using essentially flat panels of cells. In some cases, reflectors or lenses may be used to concentrate the received light onto a smaller area, increasing the light intensity and reducing the size and/or number of cells needed.

Transmission of laser power over an optical fiber to a photovoltaic receiver presents an additional challenge. The light emerging from an optical fiber is typically very intense, and forms a conical beam with a centrally-peaked, nonuniform brightness (power per unit solid angle). Systems which transmit low power (˜2 W or less electrical output) over fiber have used simple planar arrays of, typically, 1-4 photovoltaic cells arranged around the beam center, so that light is evenly divided among cells (but unevenly distributed over each cell). However, this approach is practical only for small numbers of cells which can be arranged radially around a point.

Various means of expanding a laser beam from a fiber to larger area and generating a uniform intensity “top hat” beam of a desired shape are known, using, for example, axicon lenses or lenslet arrays. However, these tend to require large transmissive optical elements and long optical paths within the receiver, and in many cases yield a circular beam which is not well matched to typically square or rectangular arrays of PV cells.

It is known to focus light through an aperture into an approximately spherical cavity lined with photovoltaic cells, such that light which is reflected from or re-emitted by one cell may be captured by another cell. However, this results in highly non-uniform illumination of cells, is bulky and difficult to fabricate, and tends to require a large number of cells to cover the inside of an entire sphere.

### SUMMARY

In an aspect of the invention, a method for converting laser light into electricity includes receiving a beam of non-uniform laser light at an expander comprising a material at least partially transparent to the beam of non-uniform laser light and having a shape symmetric about a rotational axis. The expander includes an input surface, an exit surface, and a TIR surface, arranged to reflect the beam of non-uniform laser light by total internal reflection. The receiving a beam of non-uniform laser light includes receiving the beam of non-uniform laser light at the input surface of the expander, reflecting the beam of non-uniform laser light from the TIR surface by total internal reflection such that the beam of non-uniform laser light changes direction within the expander, allowing the beam of non-uniform laser light to exit the expander at the exit surface, receiving the exiting beam at a plurality of energy conversion components (e.g., photovoltaic cells) configured to convert optical power of the exiting beam into electrical power. The input surface, the TIR surface, and exit surface of the expander are arranged to change a spatial distribution of the beam of non-uniform laser light from a less uniform distribution at the input surface to a more uniform distribution at the plurality of energy conversion components. The input surface, the TIR surface, and the exit surface may be shaped to cause two portions of the expanded beam to overlap at the member of the plurality of energy conversion components. A cross-section of the expander through its axis may have a shape including curved sides, the curved sides being part of the TIR surface, or a shape including sides having a plurality of straight line segments, the sides having a plurality of straight line segments being part of the TIR surface. The expander may include a plurality of TIR surfaces, where the method may further include reflecting the non-uniform beam of light by total internal reflection at least twice after the non-uniform beam of light enters the input surface and before the non-uniform beam of light leaves the exit surface. The method may include conducting heat away from at least one of the plurality of energy conversion components with a heat sink. The expander may be shaped to compress a height of the exiting beam transverse to its direction of travel between exiting the expander and receiving the exiting beam at a member of the plurality of energy conversion components. The method may further include modifying the nonuniform laser light before the expander expands the nonuniform laser light, for example by interposing an optic in the path of the nonuniform laser light, such as a lens, a prism, a diffuser, a filter, a mirror, or a metamaterial.

In another aspect, a method for converting laser light into electric power includes receiving a beam of non-uniform laser light at an expander having a central axis and a reflective surface selected to expand the beam of non-uniform laser light into an expanded beam, reflecting the received beam from the reflective surface as the expanded beam, directed toward a plurality of energy conversion components (e.g., photovoltaic cells) disposed to receive the expanded beam and configured to generate electric power from the expanded beam, monitoring a parameter selected from the group consisting of power, current, and voltage produced by a first subset of the plurality of energy conversion components and by a second subset of the plurality of energy conversion components, and in response to monitoring the parameter produced by the first subset and by the second subset, moving the expander relative to the received beam of non-uniform laser light, wherein moving the expander relative to the received beam of non-uniform laser light includes reducing a difference in the parameter produced by the first subset and by the second subset. The beam of non-uniform laser light may have a direction, and moving the expander relative to the beam of non-uniform laser light may include changing an angle between the direction and the central axis of the expander, for example by bringing the expander to a position wherein the central axis is approximately parallel to the direction. Moving the expander relative to the received beam of non-uniform laser light may include moving the plurality of energy conversion components. The plurality of energy conversion components may include energy conversion components disposed in a two-dimensional array surrounding the expander, in which case the first subset of the plurality of energy conversion components and the second subset of the plurality of energy conversion components may be disposed at different locations along the central axis.

In another aspect, a device for converting nonuniform laser light into electricity may include an expander having an axis and a curved surface that is configured to reflect nonuniform laser light away from the axis to expand a beam of the nonuniform laser light and an energy conversion component disposed to receive the expanded beam and configured to generate electricity from the expanded beam. The curved surface may include at least two conical segments, each shaped as a truncated cone and having a common axis, each conical segment having a selected angle of incidence to the common axis, wherein the at least two conical segments have different angles of incidence to the common axis, and the expander may include a finite number of truncated conical segments. The device may further include a reflective surface disposed between the expander and the energy conversion component and configured to further reflect the nonuniform laser light reflected from the expander toward the energy conversion component, and/or a heat sink configured to conduct heat away from the energy conversion component. The energy conversion component may include a height measured along the direction of the common axis, and the expander may include a height measured along the direction of the common axis that is longer than the height of the energy conversion component. The device may further include one or more additional energy conversion components, wherein the energy conversion component and the additional energy conversion components may be disposed symmetrically around the common axis, and may, together, form a polygonal prism shape that surrounds the expander. The device may include an optical component configured to modify the nonuniform laser light before the expander expands the nonuniform laser light, such as a lens, a prism, a diffuser, a filter, a mirror, or a metamaterial. The selected angles of incidence of the at least two conical segments may be selected to create an overlapping vertical distribution of irradiance at the energy conversion component. The device may further include a secondary reflective surface disposed to reflect the nonuniform laser light toward the expander.

In another aspect, a device for converting a beam of nonuniform laser light into electricity may include an expander having a shape symmetric about a rotational axis and a reflective surface, wherein the reflective surface includes multiple angles relative to a line parallel to the axis, the multiple angles selected to expand the beam of nonuniform laser light into an expanded beam, and a plurality of energy conversion components disposed to receive the expanded beam and configured to generate electricity from the expanded beam. The multiple angles may be selected to change a spatial distribution of energy of the beam of nonuniform laser light between the reflective surface and a member of the plurality of energy conversion components from a less uniform distribution to a more uniform distribution. The multiple angles may be selected to cause two portions of the expanded beam to overlap at the member of the plurality of energy conversion components. A cross-section of the expander through the axis may have a shape including curved sides, the curved sides being part of the reflective surface, or a shape including sides having a plurality of straight line segments, the sides having a plurality of straight line segments being part of the reflective surface. The device may further include a reflective surface disposed between the expander and the plurality of energy conversion components and configured to further reflect the nonuniform laser light reflected from the expander toward the plurality of energy conversion components. The device may further include a heat sink configured to conduct heat away from at least one of the plurality of energy conversion components. The expander may be shaped to compress the height of the reflected light beam transverse to its direction of travel between leaving the expander and reaching a member of the plurality of energy conversion components. The plurality of energy conversion components may be arranged in a polygonal prism shape. The device may further include an optical component configured to modify the nonuniform laser light before the expander expands the nonuniform laser light, such as a lens, a prism, a diffuser, a filter, a mirror, or a metamaterial. The device may further include a secondary reflective surface disposed to reflect the nonuniform laser light toward the expander.

In another aspect, a device for converting nonuniform laser light into electricity may include an expander having an axis and having a reflective surface and a plurality of energy conversion components (e.g., photovoltaic cells or groups of photovoltaic cells) disposed to receive an expanded beam and configured to generate electricity from the expanded beam. The reflective surface may have a substantially pyramidal shape characterized in that each cross-section of the shape in a plane perpendicular to the axis is a polygon having a selected number of sides, wherein the selected number of sides is the same for each cross-section of the surface, and the reflective surface may include multiple angles relative to the axis, the multiple angles selected to expand a beam of nonuniform laser light into the expanded beam. The multiple angles may be selected to change a spatial distribution of the nonuniform laser light of the beam between the reflective surface and a member of the plurality of energy conversion components from a less uniform distribution to a more uniform distribution. The selected number of sides may be the same as the number of members of the plurality of energy conversion components. The device may further include a secondary reflective surface disposed to reflect the nonuniform laser light toward the expander.

### BRIEF DESCRIPTION OF THE FIGURES

FIG. 1 illustrates a perspective, cutaway view of a device, according to an embodiment of the invention.

FIG. 2A illustrates a partial cross-section of a device, a partial cross-section of an electromagnetic radiation beam approaching the expander of the device, and a partial cross-section of the electromagnetic beam reflected by the expander, according to an embodiment of the invention.

FIG. 2B graphically illustrates the distribution of the radiation within the partial cross-section of the electromagnetic radiation approaching the expander in FIG. 2A, according to an embodiment of the invention.

FIG. 2C graphically illustrates the distribution of the radiation flux of the partial cross-section of the electromagnetic radiation approaching the expander in FIG. 2A, according to an embodiment of the invention.

FIG. 3A illustrates a partial cross-section of a device, a partial cross-section of an electromagnetic radiation beam approaching the expander of the device, and a partial cross-section of the electromagnetic beam reflected by the expander, according to another embodiment of the invention.

FIG. 3B graphically illustrates the distribution of the radiation within the partial cross-section of the electromagnetic radiation approaching the expander in FIG. 3A, according to an embodiment of the invention.

FIG. 3C graphically illustrates the distribution of the radiation flux of the partial cross-section of the electromagnetic radiation approaching the expander in FIG. 3A, according to an embodiment of the invention.

FIG. 4A illustrates a partial cross-section of a device, a partial cross-section of an electromagnetic radiation beam approaching the expander of the device, and a partial cross-section of the electromagnetic beam reflected by the expander, according to yet another embodiment of the invention.

FIG. 4B graphically illustrates the distribution of the radiation within the partial cross-section of the electromagnetic radiation approaching the expander in FIG. 4A, according to an embodiment of the invention.

FIG. 4C graphically illustrates the distribution of the radiation flux of the partial cross-section of the electromagnetic radiation approaching the expander in FIG. 4A, according to an embodiment of the invention.

FIG. 5A illustrates a partial cross-section of a device, a partial cross-section of an electromagnetic radiation beam approaching the expander of the device, and a partial cross-section of the electromagnetic beam reflected by the expander, according to still another embodiment of the invention.

FIG. 5B graphically illustrates the distribution of the radiation within the partial cross-section of the electromagnetic radiation approaching the expander in FIG. 5A, according to an embodiment of the invention.

FIG. 5C graphically illustrates the distribution of the radiation flux of the partial cross-section of the electromagnetic radiation approaching the expander in FIG. 5A, according to an embodiment of the invention.

Each of FIGS. 6A-6D illustrates a partial view of a device that includes an optical component, each according to a respective embodiment of the invention.

FIG. 7 illustrates a partial cross-section of a device, according to another embodiment of the invention.

FIG. 8A illustrates a partial cross-section of a device, a partial cross-section of an electromagnetic radiation beam approaching the expander of the device, and a partial cross-section of the electromagnetic beam reflected by the expander, according to another embodiment of the invention.

FIG. 8B graphically illustrates the distribution of the radiation within the partial cross-section of the electromagnetic radiation approaching the expander in FIG. 8A, according to an embodiment of the invention.

FIG. 8C graphically illustrates the distribution of the radiation flux of the partial cross-section of the electromagnetic radiation approaching the expander in FIG. 8A, according to an embodiment of the invention.

FIG. 9A and 9B illustrate a device that incorporates an optical component for transmitting or receiving a secondary wavelength of electromagnetic radiation, according to another embodiment of the invention.

FIG. 10 illustrates a device, according to another embodiment of the invention.

FIG. 11 illustrates a device, according to yet another embodiment of the invention.

FIG. 12 illustrates a device that uses total internal reflection (TIR) to expand a beam of electromagnetic radiation.

FIG. 13 illustrates another device that uses TIR to expand a beam of electromagnetic radiation.

FIG. 14 illustrates a device that includes features for adjusting alignment of a receiver.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high level, without detail, in order to avoid unnecessarily obscuring aspects of the present teachings. Those of ordinary skill in the art will nevertheless understand the features of these methods, procedures, components, and/or circuitry and how they may be used in the descriptions below. Other relevant material may be found in other patents and applications as follows:

| | | |
|---|---|---|
| U.S. Pat. No. 9,800,091 | Issued Oct. 24, 2017 | Aerial Platform Powered Via an |
| | | Optical Transmission Element |
| U.S. Pat. No. 10,374,466 | Issued Aug. 6, 2019 | Energy Efficient Vehicle with |
| | | Integrated Power Beaming |
| U.S. Pat. No. 10,459,114 | Issued Oct. 29, 2019 | Wireless Power Transmitter and |
| | | Receiver |
| U.S. Pat. No. 10,488,549 | Issued Nov. 26, 2019 | Locating Power Receivers |
| U.S. Pat. No. 10,580,921 | Issued Mar. 3, 2020 | Power-Over-Fiber Safety System |
| U.S. Pat. No. 10,634,813 | Issued Apr. 28, 2020 | Multi-Layered Safety System |
| U.S. Pat. No. 10,673,375 | Issued Jun. 2, 2020 | Power-Over-Fiber Receiver |
| U.S. Pat. No. 10,816,694 | Issued Oct. 27, 2020 | Light Curtain Safety System |
| U.S. Pat. No. 10,825,944 | Issued Nov. 3, 2020 | Device for Converting |
| | | Electromagnetic Radiation into |
| | | Electricity, and Related Systems and |
| | | Methods |
| U.S. Pat. No. 11,105,954 | Issued Aug. 31, 2021 | Diffusion Safety System |
| U.S. Pat. No. 11,368,054 | Issued Jun. 21, 2022 | Remote Power Safety System |
| U.S. Pat. No. 11,581,953 | Issued Feb. 14, 2023 | Dual-Use Power Beaming System |
| U.S. Pat. No. 11,867,868 | Issued Jan. 9, 2024 | Beam Projection System Having a |
| | | Light Curtain System for Detecting |
| | | Obstacles |
| U.S. Pat. No. 12,149,293 | Issued Nov. 19, 2024 | Beam Homogenization at Receiver |
| U.S. Pat. No. 12,270,630 | Issued Apr. 8, 2025 | Dual-Use Power Beaming System |
| U.S. application No. | Filed Nov. 19, 2021 | Remote Power Beam-Splitting |
| 17/613,015 | | |
| U.S. application No. | Filed Nov. 19, 2021 | Safe Power Beam Startup |
| 17/613,021 | | |
| U.S. application No. | Filed Nov. 19, 2021 | Beam Profile Monitor |
| 17/613,028 | | |
| U.S. application No. | Filed Mar. 15, 2022 | Optical Power for Electronic |
| 17/760,731 | | Switches |
| U.S. application No. | Filed Jul. 21, 2023 | Power Receiver Electronics |
| 18/262,513 | | |
| U.S. application No. | Filed May 18, 2024 | Dual Contra-Focal Homogenizer |
| 18/711,587 | | |
| U.S. application No. | Filed Oct. 18, 2024 | Power Receivers and High Power |
| 18/858,275 | | over Fiber |
| U.S. application No. | Filed Jan. 21, 2025 | Power Receiver Electronics |
| 18/997,384 | | |
| International Application | Filed May 18, 2016 | Power Beaming VCSEL |
| No. PCT/US16/33117 | | Arrangement |
| International Application | Filed Oct. 31, 2024 | High Power and Data over Optical |
| No. PCT/US24/70783 | | Fiber |
| International Application | Filed Nov. 13, 2024 | Beam-Splitting Optics for Power |
| No. PCT/US24/55769 | | Beaming |

Each of these related applications and patents is incorporated by reference herein to the extent not inconsistent herewith.

As discussed above, power beaming is becoming a viable method of powering objects in situations where it is inconvenient or difficult to run wires. For example, free-space power beaming may be used to deliver electric power via a ground-based power transmitter to power a remote sensor, to recharge a battery, or to power an unmanned aerial vehicle (UAV) such as a drone copter, allowing the latter to stay in flight for extended periods of time. Power over fiber (PoF) systems usually require optical fiber (or an equivalent) to be run from a power source to a receiver, but may nevertheless provide electrical isolation and/or other advantages over traditional copper wires which carry electricity instead of light.

It will be understood that the term “light source” is intended to encompass all forms of electromagnetic radiation that may be used to transmit energy, and not only visible light. For example, a light source (e.g., a diode laser, fiber laser, light-emitting diode, magnetron, or klystron) may emit ultraviolet, visible, infrared, millimeter wave, microwave, radio waves, and/or other electromagnetic waves, any of which may be referred to herein generally as “light.” The term “power beam” is used herein interchangeably with “light beam” to mean a high-irradiance transmission, generally directional in nature, which may be coherent or incoherent, of a single wavelength or multiple wavelengths, and pulsed or continuous. A power beam may be free-space, PoF, or may include components of each. For example, a transmitter may transmit a free-space power beam to a receiver surface, which may conduct it as light over an optical fiber to a photovoltaic (PV) cell which converts it to electricity. For the sake of readability, the description may use the term “laser” to describe a light source; nevertheless, other sources such as (but not limited to) light-emitting diodes, magnetrons, or klystrons may also be contemplated unless context dictates otherwise.

For many applications, a power receiver is arranged to receive the free-space or PoF power beam and convert it to electricity, for example using PV cells or other components for converting light to electricity (e.g., a rectenna for converting microwave power or a heat engine for converting heat generated by the light beam to electricity). For the sake of readability, this application may refer to “PV cells” with the understanding that other components having a similar function (such as but not limited to those listed above) may be substituted without departing from the scope of the application.

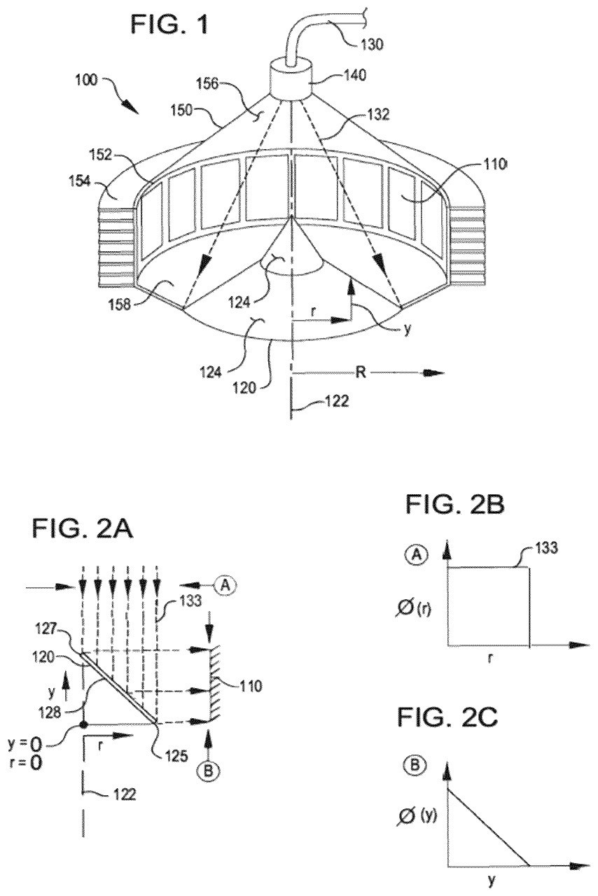

FIG. 1 illustrates a perspective, cutaway view of a device 100 for converting electromagnetic radiation into electricity, according to an embodiment of the invention. The device 100 comprises an expander 120 that includes a conical shape having an axis 122 (here an axis of symmetry for the conical shape) and a curved surface 124 that is configured to reflect a beam of electromagnetic radiation 132 (here emanating from the optical fiber 130) away from the axis 122 to expand the beam of electromagnetic radiation (also not shown). The device 100 also includes one or more energy conversion components 110 configured to receive the expanded beam of electromagnetic radiation, and to generate electricity from the expanded beam.

With the expander's curved surface 124, a beam of electromagnetic radiation that is highly concentrated—has a large radiation flux—can be converted into a beam that has a larger cross-sectional area. Moreover, one can configure, if desired, the curved surface 124 to provide a substantially uniform distribution of radiation across the expanded cross-sectional area. With such an expanded beam the one or more energy conversion components 110 can efficiently convert some of the electromagnetic radiation into electricity.

In this and other embodiments, the receiver 100 comprises a generally cylindrical array of energy conversion components 110 that include photovoltaic cells, arranged around a central reflective expander 120. In other embodiments, the energy conversion components 110 may include other means of converting light to electricity, such as thermoelectric or thermo-photovoltaic converters. The expander 120 receives light from an optical fiber 130 aligned with the axis 122 of the expander 120 and the photovoltaic array. An input optical assembly 140 may be used to couple light out of the optical fiber 130 and/or to shape the beam from the fiber 130, for example to increase its divergence. In some embodiments the assembly 140 may also comprise a connector allowing the optical fiber 130 to be detached from the receiver, and/or a bearing to allow the optical fiber 130 to rotate about an axis such as the axis 122 without becoming twisted.

Photovoltaic cells, as an example of an energy conversion component 110, operate most efficiently when the incident intensity of the electromagnetic radiation is even across the cell's surface. Laser sources often deliver electromagnetic radiation with an intensity profile that is not uniform, for example a Gaussian profile. In some embodiments, the expander shape may be designed to modify the electromagnetic radiation to a desired intensity profile at the surface of the energy conversion component 110, for example a flat (uniform) intensity profile. Other profiles are possible, depending on the configuration of the energy conversion component 110. For example, a gradient in intensity from top to bottom may be desired.

The expander 120 is configured to reflect the beam 132 from the fiber 130 onto the photovoltaic cells. The receiver 100 may be enclosed in a housing 150, which may comprise various elements such as the photovoltaic array support 152, a heat sink 154, and top and bottom covers 156 and 158.

In some embodiments, the energy conversion components 110 may be rigid, flat, and essentially rectangular, and the array of components may form a polygonal approximation to a section of a cylinder. In other embodiments, the components 110 may be rectangular and flexible, and may thus be curved into a true cylinder or close approximation thereto. In still other embodiments, the components 110 may have other shapes, for example triangular or hexagonal, and may tile the inner surface of the receiver 100 to form an approximation of a cylinder segment. In yet other embodiments, the array of components 110 may approximate a segment of a cone or a sphere. In such embodiments the components 110 may have shapes which efficiently cover the array area, e.g., trapezoidal shapes which fit into a section of a cone, or alternating rectangular and triangular components 110. Alternatively, the array area may be incompletely covered, e.g., by rectangular components 110 with triangular gaps between them.

Still referring to FIG. 1, the covers 156 and 158 are shown as conical but may be flat, dome-shaped, or some other shape suited to the optical and mechanical requirements of the receiver 100. Some fraction of electromagnetic radiation usually reflects off nearly any surface. In the case of an energy conversion device, reflected electromagnetic radiation would normally be lost and not available for conversion. In this and other embodiments, other surfaces in the vicinity of the expander 120 and energy conversion component 110 are reflective so that electromagnetic radiation which is not initially captured by the energy conversion component 110 can be reflected and have another chance to intersect the energy conversion component 110. For example, the interiors of the covers 156 and 158 may be partly or entirely reflective, either specularly reflective or diffusely reflective at the electromagnetic radiation's wavelength. Alternatively, part or all of the covers 156 and 158 may be covered with energy conversion components 110, such as photovoltaic cells that are either of the same type as the main energy conversion components 110, or of a different type, e.g., thin film photovoltaic cells. These components (or any sub-section of the components) may be connected electrically to the main receiver array of components 110, or may be coupled to a separate electrical output, for example to drive a fan or cooling pump attached to the receiver 100.

Still referring to FIG. 1, the conical shape of the expander 120 has a profile (height y as a function of radius r) which is selected to produce a desired vertical distribution of irradiance on the energy conversion components 110, such as an approximately uniform distribution. This profile may depend on the distribution of the electromagnetic radiation within the beam 132 striking the expander 120, and the size, orientation, and location of the energy conversion components 110. While the receiver 100 is not limited to any particular size, typical dimensions for an energy conversion component 110 that includes a photovoltaic cell may range from 0.1 cm² (e.g., 3 mm×3.3 mm) to 100 cm² (e.g., 10×10 cm), with the overall radius R between roughly 1 and 10 times the width of a photovoltaic cell.

The heat sink 154 is exemplary, and may be any desired heat sink capable of cooling the energy conversion components 110, including forced-air cooling in a duct or ducts, liquid cooling, or cooling via heat pipes. Energy conversion devices often require cooling in order to maintain an appropriate temperature. Flat energy conversion receivers are limited in the amount of heat sink area per unit area of receiver because only the axis perpendicular to the plane of the receiver is available. In some embodiments of the current invention, the cylindrically symmetric receiver surface can be coupled to a heat sink that can extend in two dimensions (when the height of the cylinder is less than its diameter).

FIGS. 2A-4C illustrate the effect of a conical shape 128 of an expander 120 on the distribution of irradiance (flux) on the energy conversion components 110. Each of the conical shapes 128 shown in FIGS. 2A, 3A and 4A are half of the expander's conical shape; the half of the shape not shown is simply a mirror image of the shape 128 shown about the axis 122 which in these embodiments also is an axis of symmetry for the expander's conical shape. Also, in each of the FIGS. 2A, 3A and 4A, the electromagnetic radiation 133 shown approaching the expander 120 is half of the beam that the whole expander 120 expands.

FIG. 2A-2C show the effect of reflecting a uniform “top hat” beam from a uniform cone. Each ring of radius r to r+dr illuminates an equal area of the energy conversion component 110, so the irradiance on the array goes to zero for the part illuminated by the tip 127 of the cone and is highest for the base 125 of the cone.

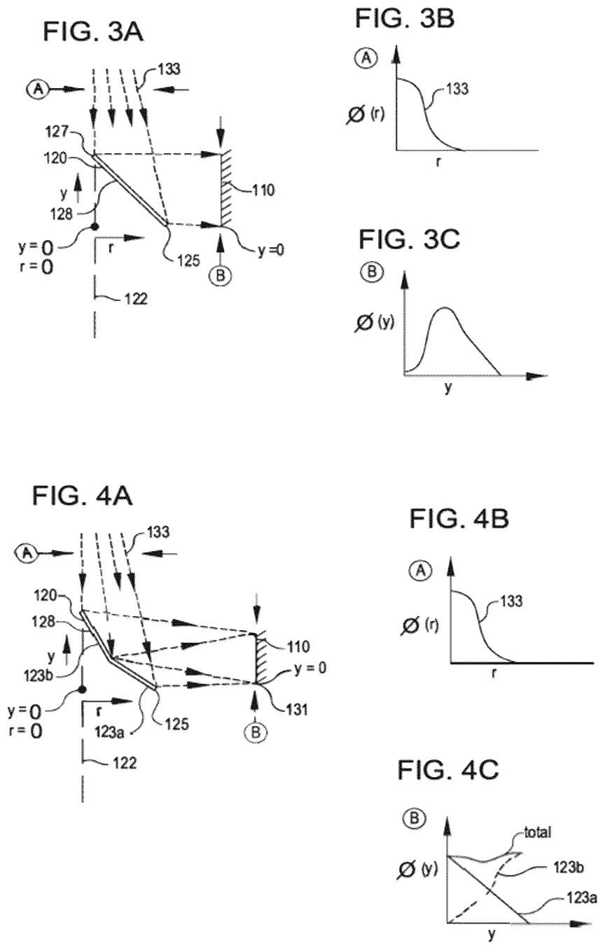

FIGS. 3A-3C show the effect of reflecting a divergent, centrally-peaked beam (approximating a Gaussian or Airy beam) from a uniform cone 128. The irradiance still goes to zero for the energy conversion component area illuminated by the tip 127 of the cone, but also falls off for the base 125 of the cone, with a maximum in between.

FIGS. 4A-4C illustrate an approach to making the array irradiance more uniform. By making the expander's conical shape 128 out of two or more conical segments 123a and 123b, with a total height greater than the height of the energy conversion component 110, the vertical distribution of the irradiance on the component 110 can be rearranged. As an example, the irradiance from the upper conical segment 123b (which decreases with height) can be overlaid with the irradiance from the lower conical segment 123a. To minimize the angle of incidence of the light on the energy conversion component 110, the base 125 of the expander 120 may be positioned lower than the bottom 131 of the energy conversion component 110. Depending on the divergence of the input beam 133 and the radius of the receiver 100, the height of the energy conversion component 110 may be less than, equal to, or greater than the height of the expander 120.

Still referring to FIG. 4A, the expander 120 may have three or more conical segments, allowing greater control over the irradiance distribution on the energy conversion component 110. In addition, the conical segments may be made individually convex or concave, to increase or decrease the height of the illuminated region.

In some embodiments, reflective surfaces may be used above and/or below the energy conversion component 110 to capture electromagnetic radiation, which would otherwise miss the component 110, and redirect it toward the component 110. These surfaces may be specular or diffuse reflectors. In some embodiments they may be used only to capture stray electromagnetic radiation, i.e., radiation scattered by outside of the main ray paths, e.g., by surface roughness on the expander 120. In other embodiments the main beam 133 path may be deliberately arranged to illuminate areas above and below the actual energy conversion component 110, and the reflectors may serve to redirect this light onto the components 110. In some embodiments, this may serve to further improve the uniformity of the component 110 illumination. In some embodiments, these reflective surfaces may be part of the top and/or bottom covers of the receiver housing.

The height, angles, and (if desired) curvatures of the individual cone segments can be found by trial and error, or by any of a variety of optimization techniques known in the art. Such optimizations may consider constraints on, for example, maximum and minimum irradiance on the energy conversion components 110, and may optimize for a variety of properties such as uniformity of illumination or insensitivity to misalignment of the input beam 133.

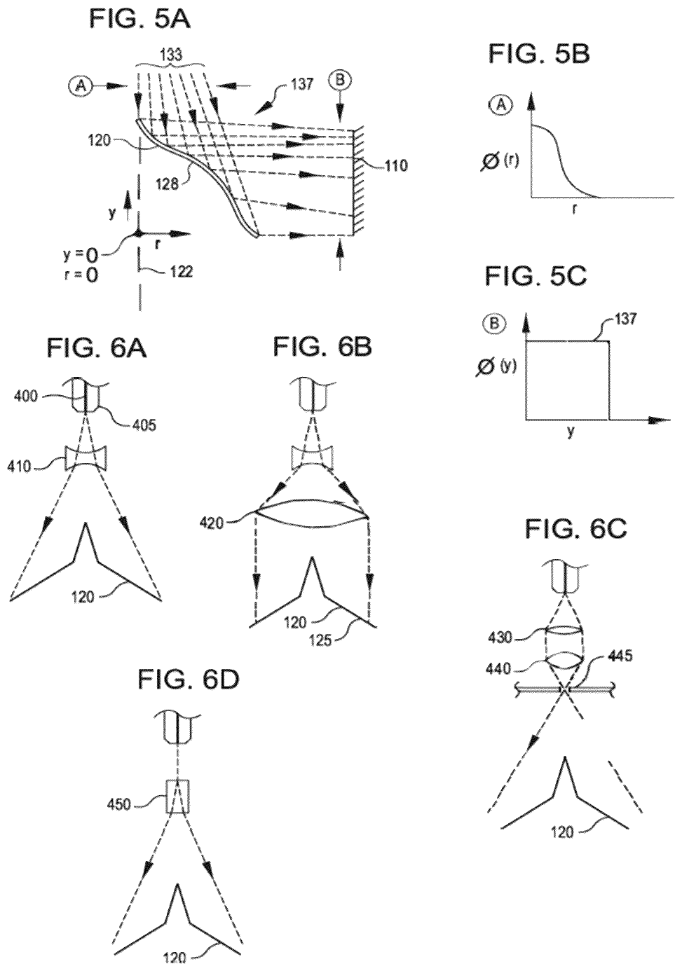

FIGS. 5A-5C illustrate an alternative approach to defining the profile of the expander 120. In this approach, the profile is locally curved to increase or decrease the vertical divergence of the radial beam 137 so that, at the energy conversion component 110 location, the irradiance is uniform (FIG. 5C) over the height of the component 110. Unlike the conical-segment approach (FIG. 4A), this approach is capable of producing a precisely-uniform distribution of irradiance of any desired height, provided the incident beam 133 profile is known.

The profile of an ideal curved expander 120 is defined by a second order differential equation. For a continuous profile and a continuous distribution of irradiance on the energy conversion component 110 (and assuming a fixed radial position R for the component 110, i.e., the component 110 is vertical) a given segment of the expander's conical shape 128 at (rₑ, yₑ) reflects electromagnetic radiation onto a segment of the component 110 at a height y_{ecc}=f1(rₑ, yₑ, y′ₑ) where y′ₑ=dyₑ/drₑ). For any particular expander profile, rₑ can be expressed as a function of yₑ, or vice versa. The corresponding irradiance on the component 110 is a function of the input irradiance 133 striking the expander 120 at rₑ, and the vertical focusing or defocusing of the beam 137 by the expander 120 (corresponding to increasing or decreasing the irradiance at the component 110). This focusing is a function of the local curvature of the expander 120, proportional to y″ₑ=d²yₑ/drₑ², and of the distance between the point of reflection and the component 110, which depends on rₑ. In general form,

$${ϕ}_{pv} [ f 1 ( {r}_{e} , {y}_{e} , {y}_{e}^{′} ) ] = {ϕ}_{in} ( {r}_{e} , {y}_{e} ) * f 2 ( {r}_{e} , {y}_{e}^{′} , {y}_{e}^{′′} )$$

Straightforward generalizations apply if the component 110 and/or the expander 120 are non-circular (R or r not constant with angle around the axis 122) or the component 110 is not vertical (R depends on y_{ecc}). This can be solved for any given expander 120 profile and input beam 133. However, inverting this to determine the expander 120 profile for a given input beam 133 and a desired ϕ_{ecc} is complex, and must in general be done numerically.

Any suitable technique may be used to fabricate the expander 120. For example, the conical-segment expander can be fabricated using conventional machining and polishing techniques suitable for flat-sided cylinders and cones. The expander 120 can also be fabricated in two or more separate pieces, each with a flat or simply-curved profile, which are then fastened (e.g., glued and/or screwed) together.

The arbitrarily-curved expander 120 may be fabricated in a variety of ways, including separately fabricating and then stacking multiple disks with appropriate diameters and flat angled or simply-curved rims. A single-piece expander 120 can also be readily fabricated using a computer-controlled lathe. The resulting part may be polished after cutting or it may have adequate surface quality as-cut.

An expander 120 may be molded in its entirety, or may be replicated using a layer of moldable material over a rigid core. A single piece mold may be used, or a two-piece mold may be used, as small seams or other imperfections will in general have little effect on the overall operation of the receiver.

Referring now to FIGS. 6A-6D, the electromagnetic radiation from the optical fiber 130 may be coupled onto the expander 120 using a variety of optical configurations. FIG. 6A illustrates an embodiment using a simple diverging lens 410, which increases the divergence of the beam 400 from the fiber 405 and thereby shortens the distance between the fiber 405 and the expander 120 for a given expander diameter. FIG. 6B illustrates an embodiment using a collimating lens 420, which decreases the angle of incidence of the electromagnetic radiation on the base 125 of the expander 120. FIG. 6C illustrates an embodiment using a combination of a collimating lens 430 and a converging lens 440 which refocuses the electromagnetic radiation from the fiber, allowing the electromagnetic radiation to enter the receiver proper through a small aperture 445. FIG. 6D illustrates an embodiment using an optical element 450 fused directly to the end of the optical fiber, eliminating the exposed fiber end and the associated reflection of electromagnetic radiation back down the fiber, along with the risk of damage to or contamination of the fiber end. Alternatively, element 450 may be butt-coupled to the fiber, or coupled via an index-matching fluid.

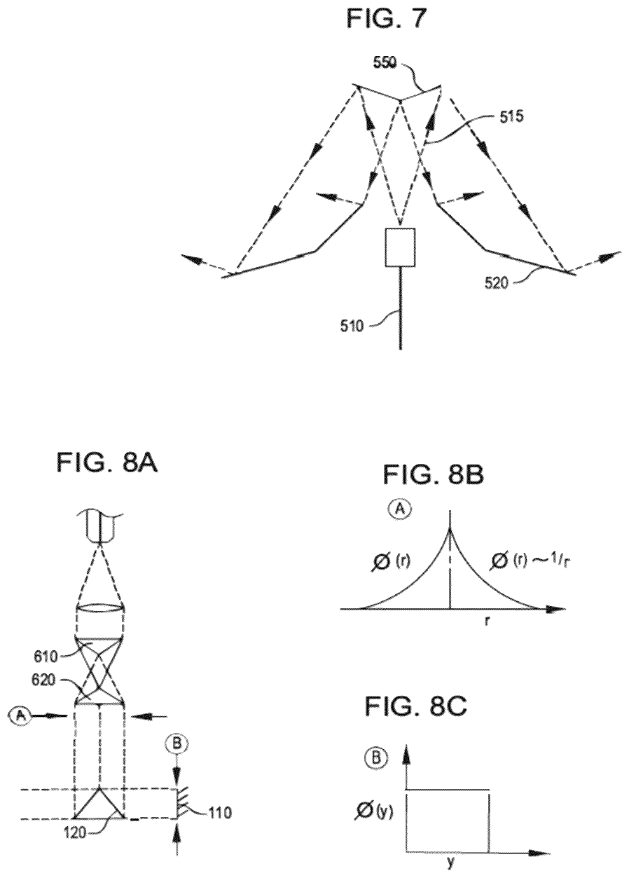

FIG. 7 illustrates an embodiment where the fiber 510 enters from the bottom of the receiver (100 in FIG. 1), and the beam 515 passes through a hole in the expander 520. Electromagnetic radiation is reflected from a shallow conical reflector 550 to create a hole in the reflected beam, avoiding reflection of electromagnetic radiation back down the fiber or onto the fiber end. This also reduces the maximum intensity of electromagnetic radiation on the expander 520 itself. In other embodiments, the fiber may enter the receiver at a point other than the center of the bottom cover, and the reflector 550 may be, for example, a tilted flat reflector.

FIGS. 8A-8C illustrate an embodiment in which the beam of electromagnetic radiation is redistributed radially allowing the expander 120 to include a conical shape that is a simple straight-sided cone. Any combination of optical elements and expander shaping may be used to produce the desired vertical distribution of flux on the energy conversion component 110. For example, in some embodiments axicon optical elements 610 and 620 may be used. In other embodiments, lenses, mirrors, optical filters (wavelength filters or polarizing filters), diffusers, prisms (such as Risley prisms to steer the beam, or anamorphic prisms to change the beam diameter or shape), each of which may be fixed and/or adjustable, may be used.

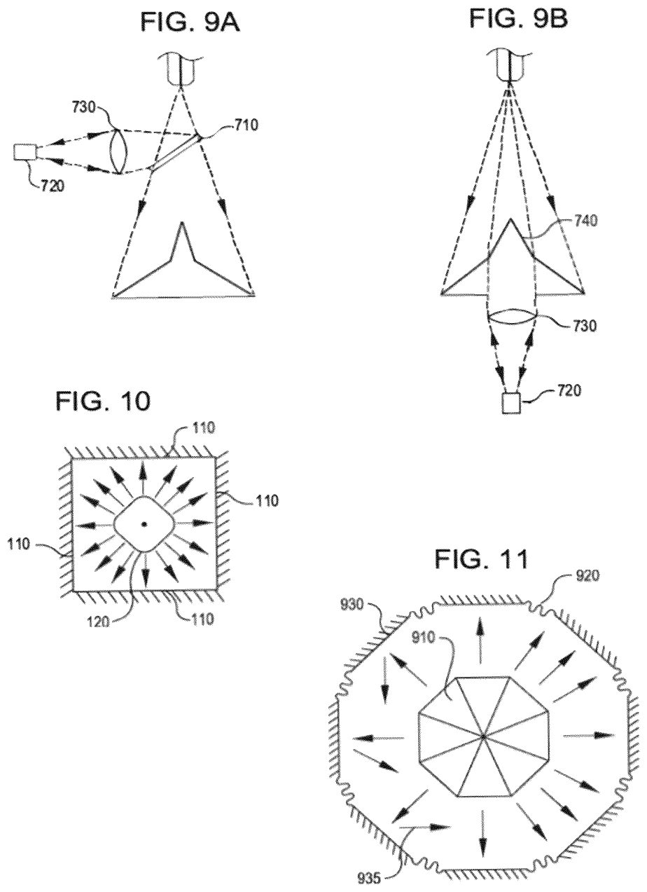

Referring now to FIG. 9A and 9B, in some cases it may be desirable to transmit or receive a second wavelength of electromagnetic radiation over the optical fiber, separate from the first wavelength being received by the energy conversion component, e.g., for communications or data transmission. In some embodiments, as shown in FIG. 9A, this second wavelength may be separated from or combined with the first wavelength by a dichroic reflector 710 incorporated into some part of the beam path. The second wavelength may be emitted or received by device 720 and focused by representative optical element 730. In other embodiments, as shown in FIG. 9B, a portion of the expander itself may be a dichroic element 740, which at least partly transmits the second wavelength while reflecting the first wavelength. Other possible optical configurations for transmitting or receiving a second wavelength will be apparent to those skilled in the art.

FIG. 10 illustrates a top view of a non-circular array of energy conversion components 110 and a corresponding non-circular expander 120. Such a non-circular array may arise because the array comprises a small number of rigid cells, or due to other constraints, for example on the space available for the receiver. The non-circular expander 120 has a radius which varies as a function of both height and rotational angle, typically with greater curvature where the array is closer to the axis, and smaller curvature where the array is farther from the axis, to provide a desired flux distribution on the energy conversion components. Such complex shapes may be fabricated by, for example, computer-controlled milling.

FIG. 11 illustrates a receiver using a pyramidal expander 910, which yields a high irradiance over a portion of the receiver circumference and negligible irradiance elsewhere. Such a configuration may be used with energy conversion components 930 which are optimized for comparatively high flux, and/or are high cost. The generally circular or polygonal configuration of the receiver allows efficient cooling of such components 930, and the expander profile may still be selected to provide uniform irradiance of the component array in the vertical direction. The space between components 930 may be filled with reflective material 920, so that light reflected or scattered from one component 930 will reflect within the receiver until it is absorbed by the same or another component 930. In some embodiments, components 930 may be deliberately oriented away from perpendicular to the receiver axis so that electromagnetic radiation 935 reflected from one component 930 will strike another component 930, or a wall of the receiver, rather than striking the expander 910 and being reflected back toward the optical fiber.

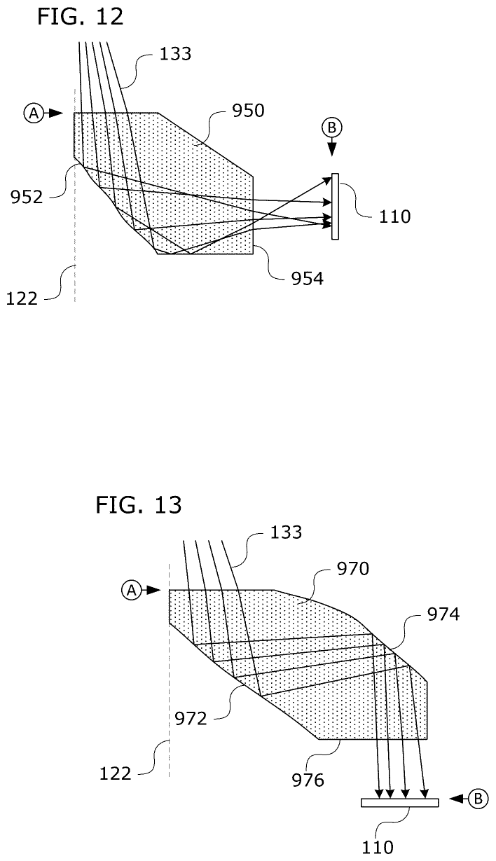

FIG. 12 illustrates a receiver using a total internal reflection (TIR) expander 950, an alternative to the reflective expanders described above. As in FIG. 4A and others described previously, FIG. 12 (and FIG. 13 below) shows a cross-sectional view of an expander, which would form an axially symmetric solid rotated about axis 122. Expander 950 has an approximately conical cavity whose profile can be seen at surface 952. As illustrated, this cavity has a curved profile analogous to the curved reflector shown in FIG. 5A, but it may also form a simple cone or a segmented cone as described above in connection with FIG. 3A and FIG. 4A. Expander 950 may be made out of any suitable material that is substantially transparent to the electromagnetic radiation, such as silica glass, transparent plastics such as polycarbonate or polyethylene, transparent crystals such as diamond, or any known material used for optical components. Electromagnetic beam 133 enters expander 950 at point A, where it is refracted according to the index of refraction of the expander material, visible as a bend in the arrows entering the expander. When light within a material strikes an internal surface at a sufficiently shallow angle, the light is totally reflected, with none escaping the material. The angle of total reflection depends upon the indices of refraction of the material and the space outside it (which could be air, vacuum, water or another liquid, or glass or another solid), according to the relationship:

$${ϑ}_{C} = {sin}^{- 1} \frac{{n}_{2}}{{n}_{1}}$$

For example, the critical angle for a reflector made of glass (n₁=1.5) in air (n₂=1) is 41.8°, and light striking a surface at an angle shallower than this will be totally reflected inside the glass reflector. Surface 952 of expander 950 is shaped such that the critical angle will not be exceeded, and each of the illustrated portions of electromagnetic beam 133 is completely reflected as shown. Some portions of electromagnetic beam 133 may be further reflected from the bottom of expander 950 as illustrated, while others may continue on to exit expander 950 without further reflections. It will be understood that surface 952 may have any arbitrary shape, so long as the critical angle will not be exceeded for at least most of incoming beam 133. Electromagnetic beam 133 exits expander 950 and continues on to energy conversion component 110 at point B. Surface 952 is chosen to have a shape that causes electromagnetic beam 133 to have a more uniform profile at point B than it has when entering expander 950 at point A (similar to the profiles shown in FIG. 5B and FIG. 5C, for example, although the beam profile at point B need not be perfectly uniform as shown in FIG. 5C, merely more uniform than the profile entering expander 950). In some embodiments (not shown), energy conversion component 110 may be placed in contact with expander 950, rather than allowing light to pass through an air gap between expander 950 and energy conversion component 110. In some such embodiments, it may be desirable to use an optical gel, epoxy, or other liquid or formerly-liquid material to optically couple energy conversion component 110 to expander 950.

FIG. 13 shows another TIR expander 970 having two shaped internally reflective surfaces. As in FIG. 12, expander 970 forms a surface of revolution about axis 122. Electromagnetic beam 133 enters expander 970 at point A, where it refracts and continues toward curved surface 972. Beam 133 is totally internally reflected toward secondary curved surface 974, where it is totally internally reflected again. Beam 133 then continues on to exit expander 970 and continues through air to energy conversion component 110 at B. In this embodiment, all energy conversion components 110 may be placed in a circle on a single plane at B, which may be convenient for manufacturing purposes.

For either the receiver shown in FIG. 12 or in FIG. 13, it may be preferable in some embodiments for the receiver to have polygonal faces, rather than forming a smooth-sided axis of rotation, analogous to the shapes shown in FIG. 10 and FIG. 11.

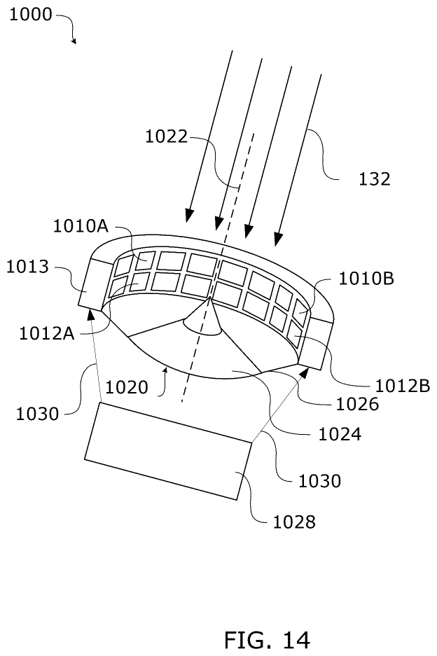

FIG. 14 shows another embodiment which may be particularly useful when the receiver is not in a fixed position relative to an optical source, although its use is not restricted to this situation. Free space power receiver 1000 has a shape similar to the power-over-fiber receiver 100 shown in FIG. 1, with expander 1020 having a curved reflective surface 1024 configured to reflect and expand a beam of electromagnetic radiation 132 toward energy conversion components 1010, 1012 and (as illustrated) having a shape including two coaxial conical segments, with central axes 1022. It will be understood that in other embodiments, surface 1024 may have any of the other shapes described above, such as the locally curved surface discussed above in connection with FIGS. 5A-5C, or any other suitable shape for accomplishing the purposes described herein, such as a simple cone. In other embodiments, rather than reflective components as illustrated, free space power receiver 1000 may use refractive components as described in correction with FIG.12 and FIG. 13. Expander 1020 is shown as rigidly coupled to support ring 1013 for energy conversion components 1010, 1012 by mechanical connectors 1026, but in some embodiments (not shown), it may be preferable for expander 1020 and energy conversion components 1010, 1012 to be movable relative to one another. Actuator 1028 is shown schematically in FIG. 14 as applying forces 1030 to support ring 1013. By moving at least a portion of power receiver 1000 so that its axis 1022 more closely aligns with incoming light 132, electromagnetic radiation reaching energy conversion components 1010, 1012 may arrive at a desirable acceptance angle, as well as other benefits as described below. While a general actuator 1028 is shown in FIG. 14, it will be understood that specific embodiments may use a variety of components to accomplish this purpose, such as linear motors, rotary motors, a hexapod positioner, a flexure stage, a three-axis translation stage, or a five-axis positioner, and those having ordinary skill in the art will understand how to select an appropriate component for a given application.

As described in copending and commonly owned international patent application no. PCT/US2020/034095, which is incorporated herein by reference to the extent not inconsistent herewith, energy conversion components may be used for positional feedback for a power receiver. In use, energy conversion components 1010, 1012 may be individually monitored (or may be monitored in subgroups), in order to determine how much energy is being converted at each component 1010, 1012 or at each subgroup, for example by monitoring power, current, and/or voltage. For example, it may be determined that energy conversion component 1010A is producing more electrical power than energy conversion component 1010B. In response, power receiver 1000 may be moved to attempt to equalize an amount of power received at each location (or to maximize a total amount of power received). Furthermore, comparison of the amount of power being produced by energy conversion component 1010A and vertically adjacent energy conversion component 1012A may allow fine adjustment of tilt of power receiver 1000 relative to incoming power beam 132.

Those of ordinary skill in the art will understand that a feedback system may monitor various combinations of current, voltage, or both at multiple cells or cell-groups as control variable(s). For a hybrid system such as the distributed wiring arrangements described in copending and commonly owned U.S. application Ser. No. 18/262,513, filed Jul. 21, 2023 and entitled “Power Receiver Electronics,” it may be preferred to monitor both current and voltage, use them to determine per-converter or per-group power, and to use that as the control input. Spatial temperature variation may also be used as a method of determining the input power distribution or may be combined with the other methods to compensate for temperature effects on converter power output.

In one embodiment, a simple X-Y motion platform may use at least three radial zones (converter groups) for input. The ring of power converters 1010, 1012 may be split into four quadrants, with the dividing lines between the quadrants aligning with the X- and Y-axes. Inputs from the four segments are then summed in adjacent pairs to create X+, X−, Y+, and Y−power totals. (This method is similar to the algorithm used by a position sensing device.) Then, the X- and Y-axes are commanded to move support ring 1013 in response to any detected imbalance along the corresponding axis (e.g., if X+ is producing more power than X−, then the motion platform is commanded to move toward X−). This may be implemented by a variety of feedback schemes that are known to those of ordinary skill in the art, such as a proportional-integral-derivative (PID) controller that uses the axial imbalance as the “error” input. Since the output from photovoltaic cells is nonlinear, following the IV curve as the cell varies from its maximum power point, the power term may be very small or effectively zero, leaving the control loop to be dominated by the current term, but this will not necessarily prevent the control loop from working effectively.

Adding tilt to the system may be most easily controlled by comparing the control variable (e.g., power, current, and/or voltage) from power converter 1010X with that from corresponding power converter 1012X (e.g., 1010A with 1012A, 1010B with 1012B, or 1010A+1010B with 1012A+1012B). Ideally, this parameter will be checked at at least three locations around the ring, for example for a set of horizontally-adjacent cells covering 120° of the circumference of the ring. The same PID-type controller discussed in connection with the X-Y motion platform should be effective for controlling pitch and yaw of the ring to align it with the direction of incoming light. Other control schemes will of course be apparent to those having ordinary skill in the art of feedback control systems and are included within the scope of this application. Combinations of the different expander configurations discussed above may also be used, including but not limited to the TIR expander shown in FIG. 12 and FIG. 13.

The preceding discussion is presented to enable a person skilled in the art to make and use the invention. Various modifications to the embodiments will be readily apparent to those skilled in the art, and the generic principles herein may be applied to other embodiments and applications without departing from the spirit and scope of the present invention. Thus, the present invention is not intended to be limited to the embodiments shown, but is to be accorded the widest scope consistent with the principles and features disclosed herein.

1-10. (canceled)

11. A method for converting laser light into electric power, comprising:
receiving a beam of non-uniform laser light at an expander having a central axis and a reflective surface selected to expand the beam of non-uniform laser light into an expanded beam;
reflecting the received beam from the reflective surface as the expanded beam, directed toward a plurality of energy conversion components disposed to receive the expanded beam and configured to generate electric power from the expanded beam;
monitoring a parameter selected from the group consisting of power, current, and voltage produced by a first subset of the plurality of energy conversion components and by a second subset of the plurality of energy conversion components; and
in response to monitoring the parameter produced by the first subset and by the second subset, moving the expander relative to the received beam of non-uniform laser light,
wherein moving the expander relative to the received beam of non-uniform laser light includes reducing a difference in the parameter produced by the first subset and by the second subset.

12. The method of claim 11, wherein the beam of non-uniform laser light has a direction, and moving the expander relative to the beam of non-uniform laser light includes changing an angle between the direction and the central axis of the expander.

13. The method of claim 12, wherein changing the angle between the direction and the central axis of the expander includes bringing the expander to a position wherein the central axis is approximately parallel to the direction.

14. The method of claim 11, wherein moving the expander relative to the received beam of non-uniform laser light includes moving the plurality of energy conversion components.

15. The method of claim 11, wherein the plurality of energy conversion components includes energy conversion components disposed in a two-dimensional array surrounding the expander.

16. The method of claim 15, wherein the first subset of the plurality of energy conversion components and the second subset of the plurality of energy conversion components are disposed at different locations along the central axis.

17. (canceled)

18. A device for converting nonuniform laser light into electricity, the device comprising:
an expander having an axis and a curved surface that is configured to reflect nonuniform laser light away from the axis to expand a beam of the nonuniform laser light, the curved surface including at least two conical segments each shaped as a truncated cone and having a common axis, each conical segment having a selected angle of incidence to the common axis, wherein
the at least two conical segments have different angles of incidence to the common axis; and
the expander includes a finite number of truncated conical segments; and
an energy conversion component disposed to receive the expanded beam and configured to generate electricity from the expanded beam.

19. The device of claim 18, further comprising a reflective surface disposed between the expander and the energy conversion component and configured to further reflect the nonuniform laser light reflected from the expander toward the energy conversion component.

20. (canceled)

21. The device of claim 18, wherein:
the energy conversion component includes a height measured along the direction of the common axis, and
the expander includes a height measured along the direction of the common axis that is longer than the height of the energy conversion component.

22. The device of claim 18, further comprising one or more additional energy conversion components, wherein the energy conversion component and the additional energy conversion components are disposed symmetrically around the common axis.

23. The device of claim 22, wherein the energy conversion component and the additional energy conversion components, together, form a polygonal prism shape that surrounds the expander.

24. The device of claim 18, further comprising an optical component configured to modify the nonuniform laser light before the expander expands the nonuniform laser light.

25. (canceled)

26. The device of claim 18, wherein the selected angles of incidence of the at least two conical segments are selected to create an overlapping vertical distribution of irradiance at the energy conversion component.

27. The device of claim 18, further comprising a secondary reflective surface disposed to reflect the nonuniform laser light toward the expander.

28. A device for converting a beam of nonuniform laser light into electricity, comprising:
an expander having a shape symmetric about a rotational axis and a reflective surface, wherein the reflective surface includes multiple angles relative to a line parallel to the axis, the multiple angles selected to expand the beam of nonuniform laser light into an expanded beam; and
a plurality of energy conversion components disposed to receive the expanded beam and configured to generate electricity from the expanded beam,
wherein the multiple angles are selected to change a spatial distribution of energy of the beam of nonuniform laser light between the reflective surface and a member of the plurality of energy conversion components from a less uniform distribution to a more uniform distribution.

29. The device of claim 28, wherein the multiple angles are selected to cause two portions of the expanded beam to overlap at the member of the plurality of energy conversion components.

30. The device of claim 28, wherein a cross-section of the expander through the axis has a shape including curved sides, the curved sides being part of the reflective surface.

31. The device of claim 28, wherein a cross-section of the expander through the axis has a shape including sides having a plurality of straight line segments, the sides having a plurality of straight line segments being part of the reflective surface.

32. The device of claim 28, further comprising a reflective surface disposed between the expander and the plurality of energy conversion components and configured to further reflect the nonuniform laser light reflected from the expander toward the plurality of energy conversion components.

33. (canceled)

34. The device of claim 28, wherein the expander is shaped to compress the height of the reflected light beam transverse to its direction of travel between leaving the expander and reaching a member of the plurality of energy conversion components.

35. The device of claim 28, wherein the plurality of energy conversion components are arranged in a polygonal prism shape.

36. The device of claim 28, further comprising an optical component configured to modify the nonuniform laser light before the expander expands the nonuniform laser light.

37. The device of claim 36, wherein the optical component includes at least one of the following: a lens, a prism, a diffuser, a filter, and a mirror.

38. The device of claim 28, further comprising a secondary reflective surface disposed to reflect the nonuniform laser light toward the expander.

39. A device for converting nonuniform laser light into electricity, comprising:
an expander having an axis and having a reflective surface, wherein the reflective surface has a substantially pyramidal shape characterized in that each cross-section of the shape in a plane perpendicular to the axis is a polygon having a selected number of sides, wherein the selected number of sides is the same for each cross-section of the surface; and the reflective surface includes multiple angles relative to the axis, the multiple angles selected to expand a beam of nonuniform laser light into an expanded beam; and
a plurality of energy conversion components disposed to receive the expanded beam and configured to generate electricity from the expanded beam,
wherein the multiple angles are selected to change a spatial distribution of the nonuniform laser light of the beam between the reflective surface and a member of the plurality of energy conversion components from a less uniform distribution to a more uniform distribution.

40. The device of claim 39, wherein the selected number of sides is the same as the number of members of the plurality of energy conversion components.

41. (canceled)

42. (canceled)

43. The device of claim 39, further comprising a secondary reflective surface disposed to reflect the nonuniform laser light toward the expander.
